(19) United States
(12) Patent Application Publication
(10) Pub. No.: US 2005/0287295 A1
(43) Pub. Date: Dec. 29, 2005

(54) Device for reflecting electromagnetic waves, particularly light and heat radiation to a regulable extent, and method for the metalization of a film with a density varying with longitudinal position according to a given function

(76) Inventor: Miklos Papp, Budapest (HU)

Correspondence Address: VENABLE LLP, P.O. BOX 34385, WASHINGTON, DC, 20045-9998, US

(21) Appl. No.: 10/510,335

(22) PCT Filed: Oct. 4, 2002
(86) PCT No.: PCT/HU02/00101

§ 371 Date: Oct. 5, 2004

(30) Foreign Application Priority Data
Oct. 8, 2001 (HU) P01 04156
Apr. 15, 2002 (HU) P02 01230

(51) Int. Cl. C23C 16/00

(52) U.S. Cl. 427/248.1

(57) ABSTRACT

The present invention relates to a device (1) for reflecting electromagnetic waves, particularly light and heat radiation to a regulable extent, wherein between two protective plates (3) substantially transparent for electromagnetic waves the device (1) comprises a sheet-like, flexible reflecting element (2) of similar width and of larger length as compared to the protective plates (3) for transmitting the electromagnetic waves to different extents and/or in different ways, the device (1) further comprises a driving means (4) for spanning the reflecting element (2) along the longitudinal directions of the protective plates (3) and moving it in the same direction. The protective plates (3) are connected to each other so as to enclose an airtight space and the reflecting element (2) is arranged between the protective plates (3) in the airtight space. The invention also relates to a method for the metallization of a film with a density varying with the longitudinal position on the film according to a given function.

The present invention relates to a device reflecting electromagnetic waves to a regulable extent, which is capable of reflecting (or transmitting) electromagnetic waves, particularly heat and light radiation, to a regulable extent. The device according to the invention is suitable to regulate (visible and UV) light, heat and radio-waves travelling to and/or from a given place and in particular suitable to darken rooms such as homes, offices, industrial and agricultural halls, etc. The invention relates also to a method for metallizing films being part of the device according to the invention with a density varying longitudinally in accordance with a given function.

For darkening homes and other rooms, i.e. for filtering light and heat radiation being transmitted by doors and windows, numerous wide-spread and well known solutions exist, such as linen shutters, wood or plastic blinds, the Venetian blind consisting of wood, metal or plastic slats moved by cords, as well as metallized films adhered to the glass of windows and doors, which, in addition to reducing the intensity of light transmitted through the windows, perform heat regulation by reflecting the light and heat radiation, too.

U.S. Pat. No. 4,848,437 discloses a pretensioned sunblind comprising a rollable multilayer material capable of alternating between a relaxed and a tensioned state, which is pretreated to inherently assume a rolled-up configuration in the relaxed state. This sunblind is intended to be used particularly in connection with motor vehicles.

According to DE 38 22 796, liquid crystal cells or similar materials limiting the light transmission when an electrical voltage is applied are arranged between transparent or translucent panes or films. This arrangement offers a rather costly solution for the darkening of glass panes of large dimensions.

U.S. Pat. No. 5,678,622 discloses a roll-up device for the heat insulation and at the same time for the light-control of windows, comprising several consecutively disposed, highly transparent foils whose reciprocal parallel distance is controllable by means of webs flexibly connected with adjacent foils. At the same time, these webs functions similarly as the slats of a Venetian blind to regulate the amount of light admitted through. In its expanded state this structure forms a heat-insulating mat with a multitude of separate, air-filled chambers and the total thickness of the mat may be as large as six centimetres. Additionally this device is highly complex and it may degrade the clear visibility through the window because of the numerous (e.g. seven) parallel foils and the connecting webs therebetween.

There is a further known solution for the controlling of electromagnetic radiation travelling through windows, the essence of which is that a transparent plastic film, which is several times as long as the window-opening and which is metallized from its one end to the other with increasing metal density is mounted on two rollers, wherein the rollers with the film are arranged on the casement of a window or between the two casements of a window with twin casements or on the glass of the window. The film is moved between the upper and the lower rollers such that always the part of the film surface ensuring appropriate screening is rolled into the window-opening. In order to move the film between the rollers, the rollers should be rotated manually by means of a belt and appropriate gearing.

However, this solution has several disadvantages. If the film is mounted in the window in the described manner, it can become dusty or dirty during use, and its cleaning is very problematic due to the thinness and the mechanical sensitivity of the film. The problem is similar when cleaning of the glass surface(s) of the window facing the thin film becomes necessary. Even the mounting of the film with varying reflectivity into the existing window structure can cause problems, owing to its sensitivity, and the need to ensure the required parallelism of the rollers of the film, i.e. the two rollers should be absolutely parallel with each other. Moreover the film should be absolutely perpendicular to the rollers. In other words the part of the film, which is spanned between the rollers should be rectangular. For similar reasons, the manual moving of the film may also provide problems, due to the large mechanical load that may emerge eventually. This solution has also the disadvantage as compared to traditional screening devices that the film is present between the two glass plates as a third layer regardless of the position thereof, which can have an influence on the visibility through the window. In addition, this solution cannot ensure total darkness due to light rays getting across at the edges of the film, as opposed to some traditional screening devices. These are the disadvantages why the above solution has not been realized so far.

An objective of the present invention is to improve the above solution by eliminating the drawbacks described and making thereby its practical realization possible.

One of the essential parts of the different embodiments of the present invention is a metallized film arranged between two protective plates, made of transparent material, which length is a multiple of the length of the window, wherein the density of the metallized coating varies along the longitudinal direction of the film in accordance with a given function. It is a further object of the present invention to provide a method for the quick, simple and therefore economical manufacturing of such films, too.

The objectives are achieved by a device for reflecting electromagnetic waves, particularly light and heat radiation to a regulable extent, wherein between two protective plates substantially transparent for electromagnetic waves the device comprises a sheet-like, flexible reflecting element of similar width and of larger length as compared to the protective plates for transmitting the electromagnetic waves to different extents and/or in different ways, the device further comprises a driving means for spanning the reflecting element along the longitudinal directions of the protective plates and moving it in the same direction. The protective plates are connected to each other so as to enclose an airtight space and the reflecting element is arranged between the protective plates in the airtight space.

Preferably, each of the two ends of the reflecting element are fastened to one of two motor driven rollers, a part of the reflecting element is rolled at least onto one of the rollers, whereas the part not rolled is spanned between the rollers. In a preferred embodiment of the invention the two rollers are arranged at an edge of the device, and at the opposite edge of the device a third roller is arranged for turning over the reflecting element. In another preferred embodiment of the invention, the two rollers are arranged at opposite edges of the device. In this case, a further, second reflecting element similar to the first one may be arranged between the protective plates.

The motors may be tubular motors placed inside the rollers or the motors are arranged outside the airtight space, and they drive the rollers through an airtight bearing support.

Preferably, the reflecting element comprises a coating on its surface. This coating may consist of a metal layer of varying density. Preferably, on the reflecting element two or more parts selected from the group below are arranged lengthwise: part without coating, part with metallization varying continuously from near 0% to near 100% reflection, part with metallization of near 100% reflection, part provided with pattern, part provided with cut-out. A part reflecting/transmitting electromagnetic waves depending on the frequencies thereof may also be arranged on the reflecting element.

Preferably, at the edges around the protective plates a light trap preventing the transmission of light is arranged. The light trap may be a paint layer or a profile around the protective plates at the edges thereof being light-absorbing at least on the side facing the reflecting element.

Preferably, between the protective plates, on one or both sides of the reflecting element threads or a net arranged substantially parallel to the reflecting element are spanned for preventing the contact of the reflecting element and the protective plates.

Preferably, on one of the sides of the device an external light sensor and an external temperature sensor, whereas at the other side thereof an internal light sensor and an internal temperature sensor are arranged, these and the conductors providing the motor or motors with electric energy are connected to a control unit optionally containing a microcontroller.

According to a preferred embodiment of the invention, the electric energy needed for the control unit and the motor or motors is obtained from solar cells and stored in a battery and the solar cells are arranged on the outer protective plate.

The reflecting element may comprise a plastic film, the protective plates may be glass plates, and the glass plates may be connected together airtight by means of metal or plastic spacers and elastic glue.

In another aspect, the objectives are achieved by a method for the metallization of a film with a density varying with the longitudinal position on the film according to a given function, comprising the steps of turning the film to be metallized over a cooled roller, below which roller a metal vapour source is arranged and moving of a covering plate between the metal vapour source and the roller according to a time function corresponding to the velocity of the film and the given function of the density varying longitudinally for modulating the intensity of the metal particle beam emitted by the metal vapour source to be deposited on the surface of the film. According to preferred embodiments of the method, a covering plate with a comb-shaped form at the periphery thereof may be moved or two or more covering plates may be moved.

The invention will be better understood from the detailed description below in conjunction with the accompanying drawings, which illustrate exemplary embodiments of the present invention.

FIG. 1 is the front view of a first embodiment of the invention;

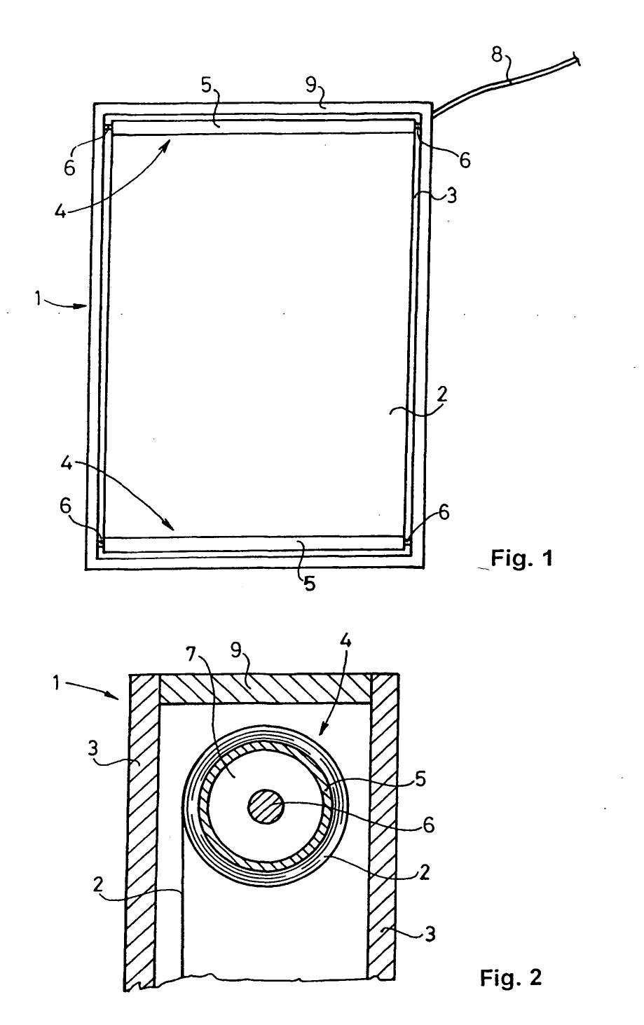

FIG. 2 is a section of the upper part of the first embodiment;

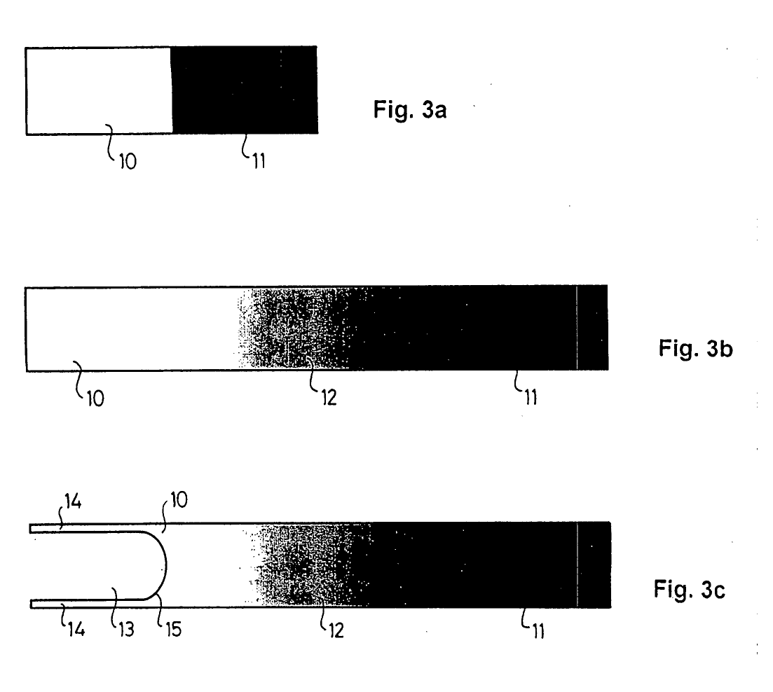

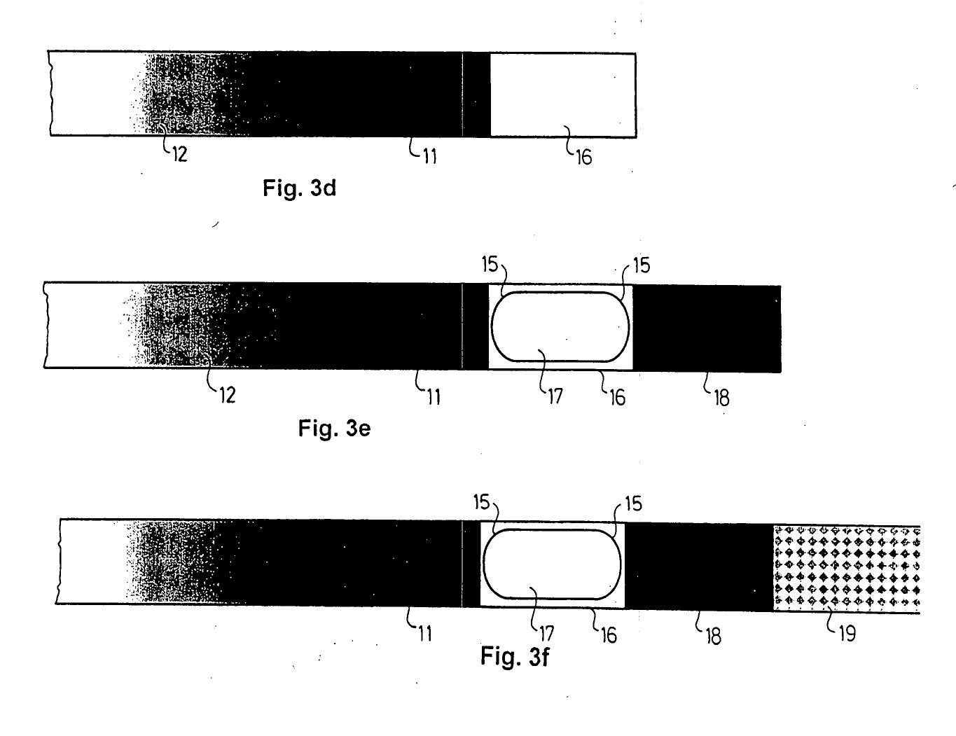

FIG. 3a-3f show different versions of the reflecting element of the invention;

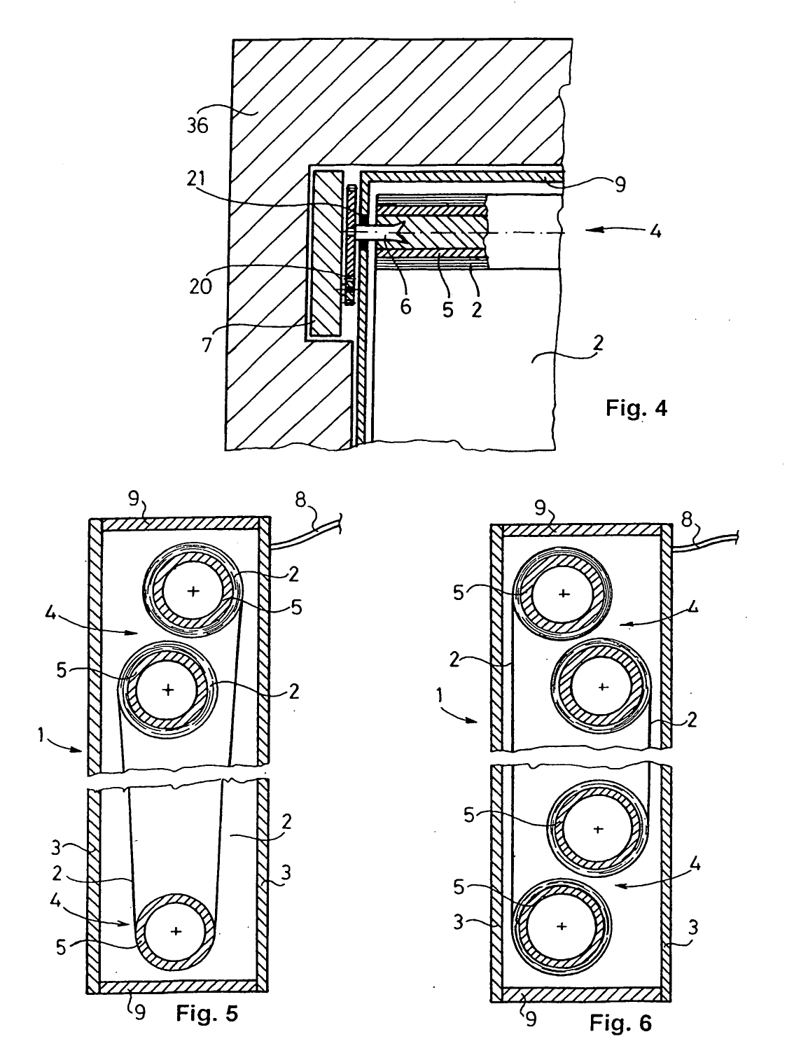

FIG. 4 is a section showing a possible version of the driving means of the device according to the invention;

FIG. 5 is a section of a second embodiment of the invention;

FIG. 6 is a section of a third embodiment of the invention;

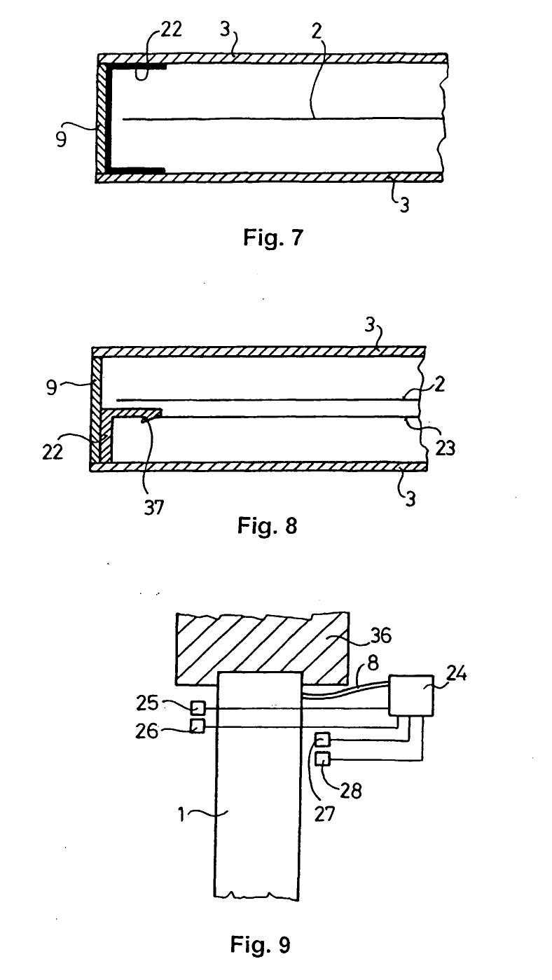

FIG. 7 is a section showing a possible version of the light trap;

FIG. 8 is a section showing another version of the light trap and the metal or plastic threads preventing the contact of the film and the glass plates;

FIG. 9 is a block diagram illustrating a microcontrolled device according to the invention;

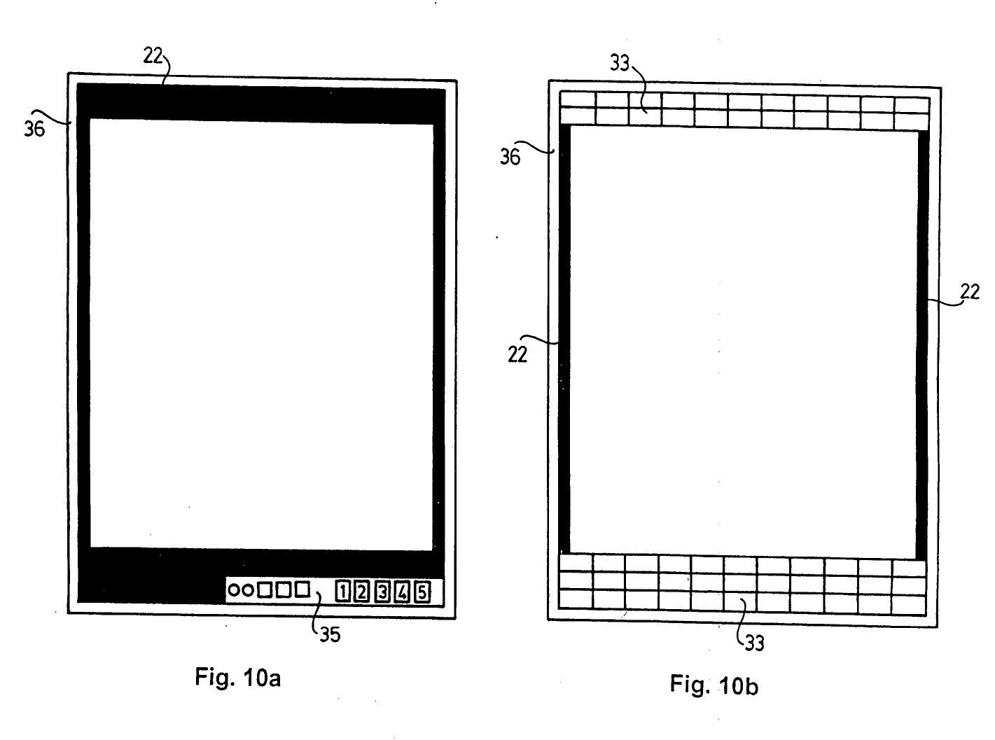

FIG. 10 shows a further embodiment of the device according to the invention mounted in a casement frame of a vertically arranged window, which has a control panel on its inner surface and solar cells on the outer surface;

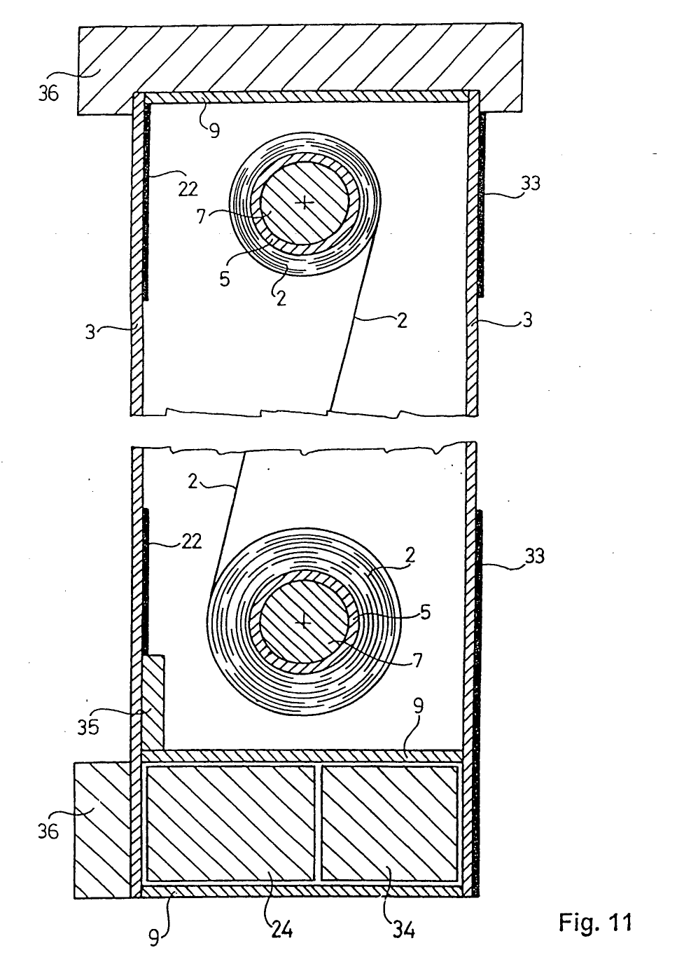

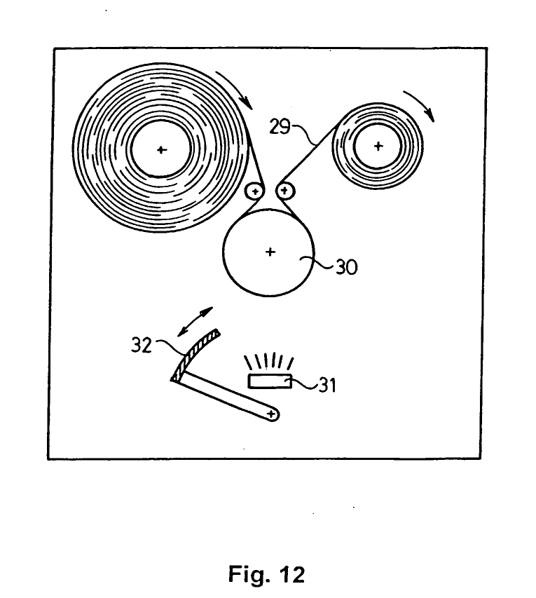

FIG. 11 is a section showing a possible arrangement of the solar cells, the control panel, the control unit and the battery in a skylight window; and

FIG. 12 is a schematic drawing illustrating the device implementing the method for the metallization of the film with a density varying longitudinally.

In FIG. 1, the front view of a first embodiment of the device 1 reflecting electromagnetic waves to a regulable extent is shown, whereas FIG. 2 is a section of the upper part of this first embodiment. The device 1 may form the heat-insulating glass of doors and windows, but it can also be used as the curtainwall of buildings or elements of the glass roofs thereof.

The device 1 comprises a reflecting element 2 situated between two protective plates 3 substantially transparent for electromagnetic waves and in particular for light. The protective plates 3 are preferably glass plates 3, but they may be made of other light-transparent material. The material of the reflecting element 2 is a transparent, flexible film, which reflects electromagnetic waves to different extents or with different parameters (e.g. with reflection/filtering depending on the frequency of the electromagnetic wave, or with mat reflection) at different parts of the reflecting element 2 owing to its particular coating (or material). The material of the film may be e.g. polyester with a thickness of the order of magnitude of micrometers, preferably with a thickness of 1-15 μm. The coating of the reflecting element 2 is preferably made of metal or other suitable chemical substance. The metallizing material is preferably aluminium, but other metals, e.g. copper or gold are also suitable. The density of the metallized coating changes lengthwise over the film. The width of the reflecting element 2 is substantially identical with that of protective plates 3, it is somewhat narrower then those, whereas the reflecting element 2 is several times as long as the protective plates 3.

The reflecting element 2 is spanned and moved along the longitudinal direction of the protective plates 3 by driving means 4. In this embodiment, the driving means 4 consists of two motor-driven rollers 5 turning over around axles 6. The length of the rollers 5 is substantially the same as the width of the reflecting element 2, i.e. the width of the film, and the rollers 5 are arranged at the two opposite edges of the glass plates 3 (e.g. at their upper and lower edges). The two ends of the film are fastened to rollers 5, and the film itself is always rolled onto at least one of rollers 5. At moving the film by the rollers 5, i.e. by winding it from one of the rollers 5 to the other, a part of the film providing the appropriate light transmission or reflection corresponding to our requirements can be brought between the glass plates 3. Turning of the rollers 5, and moving thereby the reflecting element 2 is performed by two motors 7 comprised in driving means 4, which, in this embodiment, are tubular motors 7 arranged inside the rollers 5. The motors 7 are provided with electrical energy through cable 8 and optional plugs and sockets (not shown).

It is a very important feature of the present invention that the protective plates 3 are connected to each other in an airtight manner, which is ensured in this embodiment by a spacer 9 made from a metal (e.g. aluminium) or plastic profile, to which the protective plates 3, i.e. the glass plates 3 are glued by elastic glue. Spacer 9 may be an integral part or may consist of several parts. Thus the reflecting element 2, which is arranged between the protective plates 3 is situated in an airtight space. Due to this airtight sealing, the device 1 has good heat-insulating characteristics, and no dust or dirt can get inside the device 1. Thus, the reflecting element 2, i.e. the thin film cannot be contaminated and consequently, no cleaning thereof is necessary. Similarly, the inner side of the protective plates 3, i.e. that of the glass plates 3 do not need cleaning as well, which process could lead to the damaging of the thin film. Thus, device 1 can be marketed as a finished product, which can be built into windows and doors by the manufacturers thereof, just like the already widespread heat-insulating double-glazed glass structures.

The film divides the air space between the two glass plates 3 further decreasing thereby the thermal transmittance of device 1, because the air circulations in the two divided, narrower air spaces are smaller, than the air circulation would be in a joined air space. The distance between the two glass plates 3 is at least 15 mm, or preferably gaps of 10-16 mm may be applied between the adjacent layers (between a glass plate 3 and a film; or between one of the films and another film).

In FIG. 3, different versions of the reflecting element 2 are shown. In the simplest case, in FIG. 3a, reflecting element 2 is a film twice as long as the height of the window or door, and two parts 10, 11 of substantially identical lengths follow each other lengthwise on the film. Part 10 is without any coating, whereas on part 11, a metal coating of near 100% reflection has been deposited. Thus by moving the film, a light transmitting part of any desired size can be left at one end of the window, while at its other end, no light can travel through the window. In one of the end-positions the window transmits light through over its entire surface, and in the other one, it totally reflects light.

On the film shown in FIG. 3b, between the part 10 without coating and the part 11 ensuring nearly full reflection, a part 12 of the film is arranged, which is preferably longer than the height of the window, and the metal coating on this part 12 ensures a continuous transition between the part 10 without any coating and the part 11 with near 100% light reflection. Using this version of the film, the light reflection and/or transmission of the window can be adjusted continuously according to the wish of the user by moving the rollers 5.

For ensuring best visibility through the window, it might be preferable, if in certain positions of the reflecting element 2, no film forming a third layer is situated between the two protective plates 3, i.e. between the glass plates 3. For this purpose, a cut-out 13 may be made on the film, preferably on its part 10 without coating, as is shown in FIG. 3c. In this case, the reflecting element 2 is connected to one of the rollers 5 only by means of two remaining strips 14 at the two edges of the film, i.e. in one of the end-positions of the reflecting element 2 it has no effect on the visibility regarding a predominant part of the surface of the window. The periphery of cut-out 13 substantially perpendicular to the length of the film 2 is of an arched form 15 in order to allow safe rolling up of the film, i.e. in order to prevent the crumpling and/or tearing of the film.

FIG. 3d shows a further version of the reflecting element 2 in which after the fully metalized part 11, another part 16 without coating is inserted serving the purpose that in case of fully darkened window, reflecting element 2 could be brought quickly into a fully light transmitting position without the need to rewind it through the relatively long part 12 ensuring continuously variable light transmission. Of course, a cut-out 17 similar to the cut-out 13 may also be made on the second part 16 without coating, as is shown in FIG. 3e. In this arrangement, the-nearly fully light transmitting part 16 is followed by a further, highly metallized, nearly fully light reflecting part 18; thus by means of this end of the reflecting element 2, light can be admitted either at the bottom end or at the top end of the window through a rectangular surface of any desired size, whereas through the remaining part of the surface of the window no light can get into the room. At the same time, by using the other end of the reflecting element 2 configured similarly to the former versions, particularly by means of its part 12, light transmission and light reflection can be adjusted continuously between near 0% and near 100%.

Obviously, not only cut-outs 13, 17 approaching in size the size of the window, or parts 10, 11, 12, 16, 18 metallized to different degrees may be made on reflecting element 2, but any desired patterns 19 can also be arranged on it (see FIG. 3f). Pattern 19 may also be formed so that on parts 11, 18 with near 100% reflection smaller holes or apertures are made. Pattern 19 allows for a restricted visibility to the inside through the window by an aesthetic (e.g. curtain-like) arrangement.

In addition to coatings reflecting light and heat waves to identical degrees, reflecting element 2 may be provided with coatings reflecting/filtering electromagnetic waves to an extent depending on the frequency of the electromagnetic wave (e.g. coloured coatings, or coatings reflecting heat beams to higher degree than light beams or reflecting radio-waves or reflecting only ultra-violet waves) or eventually they may give an impression of mat reflection. Similar reflecting/absorbing effect may be achieved not only by means of a coating, but also with a suitable filler added to the material of the film, e.g. with applying metal particles. Thus at moving reflecting element 2, the window can show appropriate properties corresponding to the actual demand.

It has already been described that the reflecting element 2 is moved by the driving means 4 comprising the rollers 5 and the motors 7. However, the motors 7 may not only be tubular motors 7 situated inside the rollers 5, but they may also be placed inside the frame 36 of the casement/sash of the window, outside the airtight space defined by the protective plates 3 and the spacer 9, as is shown in FIG. 4. Thus the motor 7 can easily be changed in case of a breakdown, consequently, a cheaper motor 7 with shorter lifetime can also be applied. The motor 7 drives axle 6 via gear drive 20, which axle 6 enters the airtight space through a sealed bearing support 21 (press-fit seal).

In FIG. 5, a second embodiment of the device 1 according to the invention is shown, in which the reflecting element 2 is moved by three rotating rollers 5. The two driven rollers 5 are situated at one of the edges of the device 1 beside each other, whereas the third roller 5 at the opposite edge of the device 1 serves only for turning over the film. The advantage of this embodiment is that inside the closed airtight space of the device 1 three air spaces are formed instead of two, decreasing thereby further the thermal transmittance. Further on, the motors 7 driving the rollers 5 are closer to each other, thus the electric conductors can be shorter, even using only one motor 7 may be sufficient by applying an appropriate drive (e.g. gear drive 20 or other, e.g. wire drive) so that the motor 7 is connected alternately to one of the rollers 5.

FIG. 6 shows a third embodiment of the device 1 according to the invention, in which inside the airtight space defined by the protective plates 3 and the spacer 9, two (or even more) independent reflecting elements 2 moved by driving means 4 are arranged. If the two reflecting elements 2 are provided with different coatings, their respective effect can easily be combined. Similarly to the previous embodiment, the airtight space is also divided to three (or more) air spaces by the films here. Similarly to the previous embodiment again, the use of only one motor 7 at each edges of the device 1 may be sufficient instead of using several motors 7 at the upper and lower edges.

If total darkness is required, light infiltration at the edges of the reflecting element 2 can be prevented so that light traps 22 are arranged around the reflecting element 2 at all of the four edges of the device 1. In the simplest case, the light trap 22 may be formed by one or more paint layers applied at the edges of the film and around the rollers 5 e.g. in a U-shape, as shown in FIG. 7. On the side towards the film, the colour should be light-absorbing (black), but the eventual outside layer can be of any desired colour. Instead of the U-shaped paint, U-shaped profiles may also be used. As an alternative solution, L-shaped profiles may also be placed to both side edges of the device 1 covering the edges of the film and the gap between the film and the spacer 9, wherein the side of the L-shaped profile towards the film is light-absorbing. Such light trap 22 formed from an L-shaped profile is illustrated in FIG. 8.

In order to prevent the film contacting the glass plates 3, thin threads 23 or a net made of plastic or metal and substantially parallel to the reflecting element 2 may be spanned inside the device 1, fastened for example to lugs 37 on the profiles forming the light trap 22, as shown in FIG. 8. The threads 23 or the net can be fixed, of course, in numerous different ways, e.g. it may be welded directly to the spacer 9. The distance between the threads of the net or the individual threads 23 spanned transversally is preferably in the range of 5-10 cm, while the diameter of threads is preferably about 0.1 mm. If the threads 23 or the net is made of an electrically conductive material, they are connected to the electrically grounded aluminium spacer 9 and to the other components (the motor 7, the rollers 5, the metallized side of the reflecting element 2, etc.). This way the threads 23 or the net can gather the occasionally developing electric charge on the one hand, and on the other, they keep the film in a certain distance from the protective plates 3 preventing thereby the development of triboelectric charges. Supporting the reflecting element 2 by the threads 23 or the net may be especially necessary in case of sloping skylight windows. If necessary, the threads 23 or the net may be arranged on both sides of the reflecting element 2, of course.

Contact of the reflecting element 2 and the protective plates 3 can also be prevented by applying appropriate voltage to the motors 7 such that the film is continuously spanned by two identical forces acting towards opposite directions. These spanning forces may remain at moving the film as well, but in this case, a larger force is applied in one direction than in the other.

Since inside the device 1 according to the invention the reflecting element 2 is moved by electric motors 7, the device 1 can be automated, too. For this end, cable 8 containing the wiring supplying the motors 7 with energy is connected to a controller unit 24, to which an outer light sensor 25 and an outer temperature sensor 26 situated at one of the sides of the device 1 and an inner light sensor 27 and an inner temperature sensor 28 situated at the other side of the device 1 may also be connected (see FIG. 9). This way, e.g. if the outer light is of higher intensity, by moving the part of reflecting element 2 with medium metallization into the window opening, it can function as a curtain, but if the light intensity is larger inside the room (due to internal lighting), the controller unit 24 may ensure total screening in order to provide privacy. In the hot sunshine in summer, based on the outer and inner light and temperature conditions, the controller unit 24 can regulate light and heat reflection by moving the reflecting element 2 appropriately so that it contributes to the controlling of the temperature and the light intensity actually required; and in winter, by reflecting heat beams to the inside, it makes the heating of rooms more economic. It should also be noted that the two, three or even more layers of air inside the two protective plates 3, i.e. between the two glass plates 3, result in such a small thermal transmittance value that it contributes to a more economic heating or cooling of the room in itself.

It will be apparent for a person skilled in the art that the controller unit 24 may be implemented by using a microcontroller. The controller unit 24 may be arranged on the wall next to the window where the device 1 is mounted. As an additional feature, a timer of the controller unit 24 may also be used as an “alarm-clock” admitting light into the room at a required time, which is set by the user.

If the feeding of the controller unit 24 and the motors 7 from the mains seems not to be advantageous (because no power point is available, or the cable is disturbing), the necessary electric energy may be produced by solar cells 33, charging a battery 34 and arranged directly on the outer protective glass plate 3 (see FIG. 10b for a vertically arranged window and FIG. 11 for a skylight window, where device 1 is mounted in the casement frame 36 of the window). The control unit 24 may also be situated between the protective glass plates 3, while the control panel 35 (with sensors, touch-buttons, liquid crystal display, control lamps, etc.) may be arranged on the inner part of the protective glass plates 3, facing the room. In this case there is no need for cable connection between the wall and the moving casements/sashes.

The controller unit 24 can drive one or even more devices 1 in the same time, and may be controlled manually by means of push-buttons or a remote control unit (based on radio-, infrared-, ultrasound-waves or even human voice, etc.).

According to the above, the essential element of the device 1 according to the invention is the reflecting element 2; at the production of the preferable embodiment thereof metal coating with a density varying with longitudinal position should be deposited on a transparent plastic film 29. FIG. 12 shows that the metallization of a film 29 is achieved, as usual, in vacuum so that the film 29 to be metallized is turned over with constant speed on a cooled roller 30, while a metal vapour source 31 is arranged under the roller 30. According to a possible method, the metal to be evaporated is melted in suitable (ceramic) melting-pots and then evaporated. For producing metal vapours, other methods are also known (electron or ion bombardment), which may be more advantageous from certain viewpoints (these result in finer particles), but from others, these also have drawbacks (e.g. these are more expensive). The metal vapour is deposited on the film 29, which produces thinner or thicker metal layers there, depending on the speed of the film 29 and on the intensity of the metal vapour source 31. The varying density is traditionally achieved by varying the velocity of the film 29 and/or the temperature of the melting-pots and/or the feeding rate of the metal wire to be evaporated. However, at the usual velocity (10-15 m/s) of the film 29, these do not make the quick changes in the degree of metallization (100% per some metres) necessary possible.

Proper change in the density may be achieved efficiently so that a covering plate 32 arranged above the metal vapour source 31 (i.e. above the metal evaporating melting-pots) is moved according to a time function corresponding to the velocity of the film 29 and the transition desired, i.e. a window is opened and closed in the way of the metal particle beam. To this end, it is preferable to perform the moving by electric motors with intelligent controlling (e.g. utilizing a computer or microcontroller). Moving two or more covering plates 32 of appropriate form (e.g. with comb-shaped form at their periphery) might make the regulation more flexible. Thus in this method, the change of density is achieved by moving the covering plates 32, and not by varying the intensity of the metal vapour source 31 or the velocity of the film 29, though in certain cases these parameters may also be changed.

The advantage of the device 1 reflecting electromagnetic waves to a regulable extent according to the invention is that it combines the advantages of traditional heat-insulating glass structures with those of movable films provided with a varying coating lengthwise. This sealed structure (with the small electric motors 7) can constantly protect the mechanically sensitive film from damaging forces, from dirt and from the necessity of cleaning—that is one of the main conditions of reliable long-term functioning. This compact device 1 is a very favourable solution, as it makes the production of a finished product possible by protecting the very easily damageable films and motors 7, by avoiding a complicated mounting (adjusting it completely parallel and perpendicular) on the place of use. That is also the case when only a semi-finished product is manufactured in which only one of the protective plates 3 (glass plates 3) is present, and this semi-finished product is later glued to one of the glass surfaces of an existing window in an airtight manner (eventually on the site). All these together results in practical applicability, realizability and quality mass-production—as opposed to the earlier solutions. Additionally, the third layer of the reflecting film divides the air space between the two protective plates 3 for two (or more) spaces, so the heat insulation is increased but by applying cut-outs 13, 17, the third layer between the glass plates 3 does not have an influence on the visibility through the window, while the film may remain connected to both rollers 5 by means of the two strips 14. By using the embodiments described hereinabove, total light-tightness can be realized, the adhesion of the film to the glass plates 3 can be prevented, and by means of the controller unit 24, the device 1 can be fully automated and can contribute to making the heating and cooling of rooms more economic. In addition, the plastic film 29 with varying metallization can be manufactured simply and economically using the method described.

1. Device for reflecting electromagnetic waves, particularly light and heat radiation to a regulable extent, wherein between two protective plates (3) substantially transparent for electromagnetic waves the device (1) comprises a sheet-like, flexible reflecting element (2) of similar width and of larger length as compared to the protective plates (3) for transmitting the electromagnetic waves to different extents and/or in different ways, the device (1) further comprises a driving means (4) for spanning the reflecting element (2) along the longitudinal directions of the protective plates (3) and moving it in the same direction characterized in that the protective plates (3) are connected to each other so as to enclose an airtight space and the reflecting element (2) is arranged between the protective plates (3) in the airtight space.

2. The device according to claim 1 characterized in that each of the two ends of the reflecting element (2) are fastened to one of two motor (7) driven rollers (5), a part of the reflecting element (2) is rolled at least onto one of the rollers (5), whereas the part not rolled is spanned between the rollers (5).

3. The device according to claim 2 characterized in that the two rollers (5) are arranged at an edge of the device (1), and at the opposite edge of the device (1) a third roller (5) is arranged for turning over the reflecting element (2).

4. The device according to claim 2 characterized in that the two rollers (5) are arranged at opposite edges of the device (1).

5. The device according to claim 4 characterized in that between the protective plates (3) a further, second reflecting element (2) is arranged, the two ends thereof are fastened to two further rollers (5) driven by motors (7) and arranged at the two opposite edges of the device (1), a part of the second reflecting element (2) is rolled at least onto one of the further rollers (5), whereas the part not rolled is spanned between the further rollers (5).

6. The device according to claim 2 characterized in that the motors (7) are tubular motors (7) placed inside the rollers (5).

7. The device according to claim 2 characterized in that the motor (7) or motors (7) are arranged outside the airtight space, and they drive the rollers (5) through an airtight bearing support (21).

8. The device according to claim 2 characterized in that the reflecting element (2) comprises a coating on its surface.

9. The device according to claim 8 characterized in that the coating consists of a metal layer of varying density.

10. The device according to claim 9 characterized in that on the reflecting element (2) two or more parts (10, 11, 12, 16, 18) selected from the group below are arranged lengthwise: part (10, 16) without coating, part (12) with metallization varying continuously from near 0% to near 100% reflection, part (11, 18) with metallization of near 100% reflection, part provided with pattern (19), part provided with cut-out (13, 17).

11. The device according to claim 1 characterized in that a part reflecting/transmitting electromagnetic waves depending on the frequencies thereof is arranged on the reflecting element (2).

12. The device according to claim 1 characterized in that at the edges around the protective plates (3) a light trap (22) preventing the transmission of light is arranged.

13. The device according to claim 12 characterized in that the light trap (22) is a paint layer or a profile around the protective plates (3) at the edges thereof being light-absorbing at least on the side facing the reflecting element (2).

14. The device according to claim 1 characterized in that between the protective plates (3), on one or both sides of the reflecting element (2) threads (23) or a net arranged substantially parallel to the reflecting element (2) are spanned for preventing the contact of the reflecting element (2) and the protective plates (3).

15. The device according to claim 2 characterized in that on one of the sides of the device (1) an external light sensor (25) and an external temperature sensor (26), whereas at the other side thereof an internal light sensor (27) and an internal temperature sensor (28) are arranged, these and the conductors providing the motor (7) or motors (7) with electric energy are connected to a control unit (24) optionally containing a microcontroller.

16. The device according to claim 2 characterized in that the electric energy needed for the control unit (24) and the motor (7) or motors (7) is obtained from solar cells (33) and stored in a battery (34) and the solar cells (33) are arranged on the outer protective plate (3).

17. The device according to claim 1 characterized in that the reflecting element (2) comprises a plastic film, the protective plates (3) are glass plates (3), and the glass plates (3) are connected together airtight by means of metal or plastic spacers (9) and elastic glue.

18. Method for the metallization of a film with a density varying with the longitudinal position on the film according to a given function, comprising the step of turning the film (29) to be metallized over a cooled roller (30), below which roller (30) a metal vapour source (31) is arranged characterized in that the method comprises the step of moving of a covering plate (32) between the metal vapour source (31) and the roller (30) according to a time function corresponding to the velocity of the film (29) and the given function of the density varying longitudinally for modulating the intensity of the metal particle beam emitted by the metal vapour source (31) to be deposited on the surface of the film (29).

19. The method according to claim 18 characterized in that a covering plate (32) with a comb-shaped form at the periphery thereof is moved.

20. The method according to claim 18 characterized in that two or more covering plates (32) are moved.
